(19) United States
(12) Patent Application Publication
(10) Pub. No.: US 2008/0272361 A1
(43) Pub. Date: Nov. 6, 2008

(54) High Density Nanotube Devices

(75) Inventor: Brian Y. Lim, Simi Valley, CA (US)

Correspondence Address: AKA CHAN LLP, 900 LAFAYETTE STREET, SUITE 710, SANTA CLARA, CA, 95050, US

(73) Assignee: ATOMATE CORPORATION, Simi Valley, CA (US)

(21) Appl. No.: 12/114,540

(22) Filed: May 2, 2008

Related U.S. Application Data
(60) Provisional application No. 60/915,478, filed on May 2, 2007.

(51) Int. Cl. H01L 29/06; H01L 21/336

(52) U.S. Cl. 257/9; 438/197; 977/700; 257/E29.005

(57) ABSTRACT

Carbon-nanotube-based devices or nanowire-based devices are formed in multiple layers to obtain higher density of such devices. The layers may be all similar such as all carbon-nanotube-based transistors. Or they may be different, such as one layer with nanowire devices and another layer with nanotube devices. Or some layers such as the bottom layer may be based on silicon devices and another layer with nanotube devices. Traditional interconnects and vias may be used to connect layers and electrodes, or nanoscale materials such as nanotubes or nanowires may be used as interconnects or vias.

### CROSS-REFERENCE TO RELATED APPLICATION

This application claims the benefit of U.S. provisional patent application 60/915,478, filed May 2, 2007, which is incorporated by reference along with all other references cited in this application.

### BACKGROUND OF THE INVENTION

The present invention relates to the field of carbon nanotube technology and more specifically to techniques of achieving high density for carbon-nanotube-based devices.

The age of information and electronic commerce has been made possible by the development of transistors and electronic circuits, and their miniaturization through integrated circuit technology. Integrated circuits are sometimes referred to as “chips.” Many numbers of transistors are used to build electronic circuits and integrated circuits. Modern microprocessor integrated circuits have over 50 million transistors and will have billions of transistors in the future.

Some type of circuits include digital signal processors (DSPs), amplifiers, dynamic random access memories (DRAMs), static random access memories (SRAMs), erasable programmable read only memories (EPROMs), electrically erasable programmable read only memories (EEPROMs), Flash memories, microprocessors, application specific integrated circuits (ASICs), and programmable logic. Other circuits include amplifiers, operational amplifiers, transceivers, power amplifiers, analog switches and multiplexers, oscillators, clocks, filters, power supply and battery management, thermal management, voltage references, comparators, and sensors.

Electronic circuits have been widely adopted and are used in many products in the areas of computers and other programmed machines, consumer electronics, telecommunications and networking equipment, wireless networking and communications, industrial automation, and medical instruments, just to name a few. Electronic circuits and integrated circuits are the foundation of computers, the Internet, voice over IP (VoIP), and on-line technologies including e-mail, instant messenger, and the World Wide Web (WWW).

There is a continuing demand for electronic products that are easier to use, more accessible to greater numbers of users, provide more features, and generally address the needs of consumers and customers. Integrated circuit technology continues to advance rapidly. With new advances in technology, more of these needs are addressed. Furthermore, new advances may also bring about fundamental changes in technology that profoundly impact and greatly enhance the products of the future.

The building blocks in electronics are electrical and electronic elements. These elements include transistors, diodes, resistors, and capacitors. There are many numbers of these elements on a single integrated circuit. Improvements in these elements and the development of new and improved elements will enhance the performance, functionality, and size of the integrated circuit.

An important building block in electronics is the transistor. In fact, the operation of almost every integrated circuit depends on transistors. Transistors are used in the implementation of many circuits. Improving the characteristics and techniques of making transistors will lead to major improvements in electronic and integrated circuit.

Presently silicon-based metal-oxide-semiconductor field-effect transistors (MOSFETs) are the workhorses of electronic systems and power electronics systems. However, demand for increasing performance requirements is pushing the boundaries of silicon material. It is desirable to have transistors with improved characteristics, especially transistors having higher current density, higher thermal conductivity, and higher switching frequency.

Therefore, there is a need to provide improved carbon nanotube transistor and device technology, and techniques for packaging such technology.

### BRIEF SUMMARY OF THE INVENTION

The invention is a method for achieving high density of carbon-nanotube-based devices. It is also applicable to nanowire-based devices. The devices include transistors, diodes, logic devices, switches, and other electronic devices. The invention uses multiple layers of horizontally situated devices, where there is a bottom layer which may be on a substrate and subsequent layers are built directly on top of the preceding layer. The layers may be all similar such as all carbon-nanotube-based transistors. Or they may be different, such as one layer with nanowire devices and another layer with nanotube devices. Or some layers such as the bottom layer may be based on silicon devices and another layer with nanotube devices. Traditional interconnects and vias may be used to connect layers and electrodes, or nanoscale materials such as nanotubes or nanowires may be used as interconnects or vias.

The invention allows for significantly increased density of nanotube or nanowire devices, or both, on a single chip or die. The multiple levels or layers can be similar or different, allowing for more integrated devices. It is also silicon and bulk semiconductor compatible. The number of layers may be 2 or more, 3 or more, 4 or more, 5 or more, 6 or more, 7 or more, 8 or more, 9 or more, 10 or more, 11 or more, 12 or more, or even 50 or greater.

This invention uses a structure that is layered vertically but based on horizontal devices. The invention will provide high density nanotube or nanowire based devices, or devices with combinations of nanotubes and nanowires. Examples of some devices include transistors, diodes, logic devices, switches, and others. Multiple levels of devices are built or fabricated on top of one another, where a bottom layer is generally supported by substrates such as silicon or metal or insulator or semiconductor. The devices within the layers may be similar or different. For example, some levels may contain nanotube transistors and another level may contain nanowire diodes.

Conventional silicon technology may be included in one of the layers or multiple layers and integrated with nanotube or nanowires, or both, in other layers. For example, the bottom or first layer may include CMOS devices such as CMOS transistors, inverters, and gates. These CMOS devices will connect to nanotube or nanowire devices in other layers. Nanowires or nanotubes, or both, may be used as interconnects or vias, or both, for connecting electrodes and devices through the levels. Conventional interconnection techniques may also be used.

The density of devices is increased by increasing the number of levels or layers. There may be 2 or more layers, 3 or more layers, 4 or more layers, 5 or more layers, 6 or more layers, 7 or more layers, 8 or more layers, 9 or more layers, 10 or more layers, 11 or more layers, 12 or more layers, or even 50 or greater. By increasing the layers, the current density may be increased significantly.

In an implementation, the invention is a structure including: a substrate; a first layer formed on the substrate, the first layer including a first electrode interdigitated with a second electrode; a first group of nanotubes connected to the first and second electrodes; a second layer including an insulating material formed on the first layer; a third layer including a first gate material formed on the second layer, where the first gate material is positioned above the first set of nanotubes; and a fourth layer including an insulating material formed on the third layer.

The structure may further include: a fifth layer formed on the fourth, the fifth layer including a third electrode interdigitated with a fourth electrode; a second group of nanotubes connected to the third and fourth electrodes; and a sixth layer including an insulating material formed on the fifth layer. The gate material may be polysilicon or metal. The second group of nanotubes may be formed directly above the gate material.

In an implementation, the invention is a structure including: a substrate; a first layer formed on the substrate, the first layer including a first electrode interdigitated with a second electrode; a first group of nanowires connected to the first and second electrodes; a second layer including an insulating material formed on the first layer; a third layer formed above the second layer, the second layer including a third electrode interdigitated with a fourth electrode; and a second group of nanowires connected to the third and fourth electrodes.

In an implementation, the invention is a structure including: a substrate; a first layer formed on the substrate, the first layer including a first electrode interdigitated with a second electrode; a first group of nanotubes connected to the first and second electrodes; a second layer including an insulating material formed on the first layer; a third layer formed above the second layer, the second layer including a third electrode interdigitated with a fourth electrode; and a second group of nanotubes connected to the third and fourth electrodes. The nanotubes may be single-walled carbon nanotubes or multiwalled carbon nanotubes.

In an implementation, the invention is a method including: forming on a first layer, a first electrode including first fingers; forming on the first layer a second electrode including second fingers, where the second fingers are interdigitated with the first fingers; forming a second layer above the first layer; forming a gate electrode in a third layer above the second layer, where the gate electrode is above at least a portion of the first and second fingers; forming a fourth layer above the third layer; forming on a fifth layer, above the fourth layer, a third electrode including third fingers; and forming on the fifth layer a fourth electrode including fourth fingers, where the fourth fingers are interdigitated with the third fingers, and the gate electrode is below at least a portion of the fourth and fifth fingers.

The method may include: forming nanotubes on the first layer, each nanotube connected to the first and second electrodes; and forming nanotubes on the fifth layer, each nanotube connected to the third and fourth electrodes. The method may include: forming nanowires on the first layer, each nanowire connected to the first and second electrodes; and forming nanowires on the fifth layer, each nanowire connected to the third and fourth electrodes. The method may include: forming nanotubes on the first layer, each nanotube connected to the first and second electrodes; and forming nanowires on the fifth layer, each nanowire connected to the third and fourth electrodes.

In an implementation, the method includes: applying a first voltage on the gate electrode; and applying a voltage potential across the first and second electrodes sufficient to cause current to flow through undesirable nanotubes of the nanotubes on the first layer, but current does not flow through desirable nanotubes. This will burn-off the undesirable nanotubes. The first voltage can be a negative voltage, which will shut off the desirable nanotubes to prevent them from conducting. Under the same conducts, the undesirable nanotubes will conduct sufficiently to burn off.

In an implementation, the invention is a method including: forming on a first layer, a first electrode including first fingers; forming on the first layer a second electrode including second fingers, where the second fingers are interdigitated with the first fingers; forming a first set of nanotubes connected to the first and second electrodes, where each nanotube includes a concentric gate surrounding the nanotube; forming a second layer above the first layer; forming on a third layer, above the second layer, a third electrode including third fingers; forming on the third layer a fourth electrode including fourth fingers, where the fourth fingers are interdigitated with the third fingers; and forming a second set of nanotubes connected to the third and fourth electrodes, where each nanotube has a concentric gate surrounding the nanotube. Each nanotube can be a single-walled carbon nanotube.

In an implementation, the invention is a method including: forming on a first layer, a first electrode including first fingers; forming on the first layer a second electrode including second fingers, where the second fingers are interdigitated with the first fingers; forming a first set of nanotube-nanowire devices connected to the first and second electrodes, where each nanotube includes a concentric gate surrounding the nanotube; forming a second layer above the first layer; forming on a third layer, above the second layer, a third electrode including third fingers; forming on the third layer a fourth electrode including fourth fingers, where the fourth fingers are interdigitated with the third fingers; and forming a second set of nanotube-nanowire devices connected to the third and fourth electrodes, where each nanotube includes a concentric gate surrounding the nanotube.

Other objects, features, and advantages of the present invention will become apparent upon consideration of the following detailed description and the accompanying drawings, in which like reference designations represent like features throughout the figures.

### BRIEF DESCRIPTION OF THE DRAWINGS

FIG. 1 shows a computing system incorporating the invention.

FIG. 2 shows a motor vehicle system incorporating the invention.

FIG. 3 shows a telecommunications system incorporating the invention.

FIG. 4 shows a block diagram of a system incorporating the invention.

FIG. 5 shows a circuit symbol for a carbon nanotube transistor.

FIG. 6 shows a DC-to-AC inverter circuit using carbon nanotube transistors.

FIG. 7 shows a DC-DC converter circuit using carbon nanotube transistors.

FIG. 8 shows a top view of a horizontal structure with nanotubes or nanowires between two electrodes.

FIG. 9 shows a top view of a structure with interdigitated electrodes for nanotubes or nanowires.

FIG. 10 shows a top view of a substrate or integrated circuit die with a number of interdigitated structures for nanotubes or nanowires.

FIG. 11 shows a perspective view of a substrate with a single layer of interdigitated structures for nanotubes or nanowires.

FIG. 12 shows a cross-sectional view of a substrate with multiple layers of structures with nanotubes or nanowires.

FIG. 13 shows a perspective view of a multilayer structure with interconnects and vias for electrical connection to the various device levels.

### DETAILED DESCRIPTION OF THE INVENTION

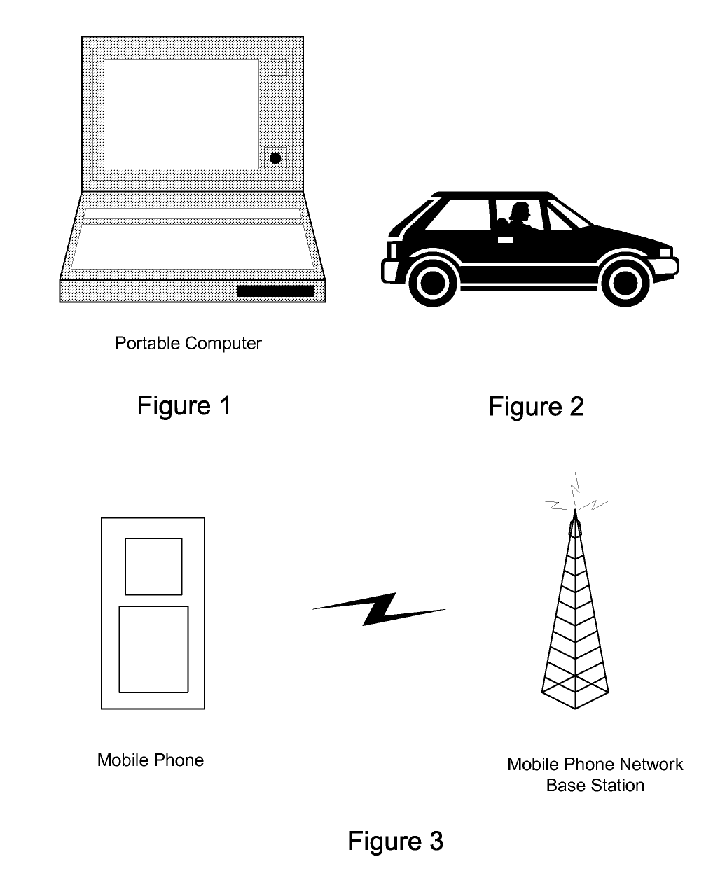

FIG. 1 shows an example of an electronic system incorporating one or more carbon nanotube transistors or other nanotube devices of the invention, or combinations of these. Carbon nanotube devices are described in U.S. patent application Ser. Nos. 11/162,548, filed Sep. 14, 2005, and 11/276,076, filed Feb. 13, 2006. These applications are incorporated by reference along with all other references cited in this application.

The invention provides innovative stacking methods for carbon-nanotube-based transistors, diodes, and rectifiers, in single-chip or multichip processes. The devices may be stacked with similar devices or with different devices, e.g., integrated circuits, noncarbon-nanotube-based devices, or other nanostructure based devices.

In a single chip stacking process, one device layer may be formed on a substrate, e.g. silicon or metal. An intermediate layer including device passivation and an optional heat spreading section is formed on top of the first device layer. A second device layer is then fabricated on top of the intermediate layer. This may be repeated for a third layer, a fourth layer, and so on. The carbon-nanotube-based transistor, diode, or rectifier layer may be all of the device layers, or may be incorporated with different device layers. For example, the carbon-nanotube-based transistor, diode, or rectifier device layer may be the second layer, where the first layer is a silicon or other based integrated circuit or logic device layer, or a nanowire based device layer, or a molecular electronics based device layer.

Electronic systems come in many different configurations and sizes. Some electronic systems are portable or handheld. Such portable systems typically may be battery operated. The battery is typically a rechargeable type, such as having nickel cadmium (NiCd), nickel metal hydride (NiMH), lithium ion (Li-Ion), lithium polymer, lead acid, or another rechargeable battery chemistry. The system can operate for a certain amount of time on a single battery charge. After the battery is drained, it may be recharged and then used again.

In a specific embodiment, the electronic system is a portable computing system or computer, such as a laptop or notebook computer. A typical computing system includes a screen, enclosure, and keyboard. There may be a pointing device, touchpad, or mouse equivalent device having one or more buttons. The enclosure houses familiar computer components, some of which are not shown, such as a processor, memory, mass storage devices, battery, wireless transceiver, and the like. Mass storage devices may include mass disk drives, floppy disks, magnetic disks, fixed disks, hard disks, CD-ROM and CD-RW drives, DVD-ROM and DVD-RW drive, flash and other nonvolatile solid-state storage drives, tape storage, reader, and other similar devices, and combinations of these.

Other examples of portable electronics and battery-operated systems include electronic game machines (e.g., Sony PlayStation® Portable and Nintendo DS), DVD players, personal digital assistants (PDAs), remote controls, mobile phones, remote controlled robots and toys, power tools, still and movie cameras, medical devices, radios and wireless transceivers, and many others. The transistor of the invention may be used in any of these and other electronic and battery-operated systems to provide similar benefits.

Transistors or rectifying devices of the invention, or combinations of these, may be used in various circuits of electronic systems including circuitry for the rapid recharging of the battery cells and voltage conversion, including DC-DC conversion. For example, each laptop power supply typically has 8 power transistors. Transistors of the invention may be used in circuitry for driving the screen of the system. The screen may be a flat panel display such as a liquid crystal display (LCD), plasma display, or organic light emitting diode (OLED) display. Transistors of the invention may be used in circuitry for the wireless operation of the system such as circuitry for wireless networking (e.g., Wi-Fi, 802.11a, 802.11b, 802.11g, or 802.11n) or other wireless connectivity (e.g., Bluetooth).

FIG. 2 shows an example of a vehicle incorporating one or more carbon nanotube transistors or rectifying devices of the invention, or combinations of these. Although the figure shows a car example, the vehicle may be a car, automobile, truck, bus, motorized bicycle, scooter, golf cart, train, plane, boat, ship, submarine, wheelchairs, personal transportation devices (e.g., Segway Human Transporter (HT)), or other. In a specific embodiment, the vehicle is an electric vehicle or hybrid-electric vehicle, whose motion or operation is provided, at least in part, by electric motors.

In an electric vehicle, rechargeable batteries, typically lead acid, drive the electric motors. These electric or hybrid-electric vehicles include transistors or devices of the invention in, among other places, the recharging circuitry used to recharge the batteries. For a hybrid-electric vehicle, the battery is recharged by the motion of the vehicle. For a fully electric vehicle, the battery is charged via an external source, such as an AC line or another connection to a power grid or electrical power generator source. The vehicular systems may also include circuitry with transistors of the invention to operate their on-board electronics and electrical systems.

FIG. 3 shows an example of a telecommunications system incorporating one or more carbon nanotube transistors or rectifying devices of the invention, or combinations of these. The telecommunications system has one or more mobile phones and one or more mobile phone network base stations. As described above for portable electronic devices, each mobile phone typically has a rechargeable battery that may be charged using circuitry with transistors or devices of the invention. Furthermore, for the mobile phone or other wireless device, there may be transceiver or wireless broadcasting circuitry implemented using transistors of the invention. And a mobile phone network base station may have transceiver or broadcasting circuitry with transistors or devices of the invention.

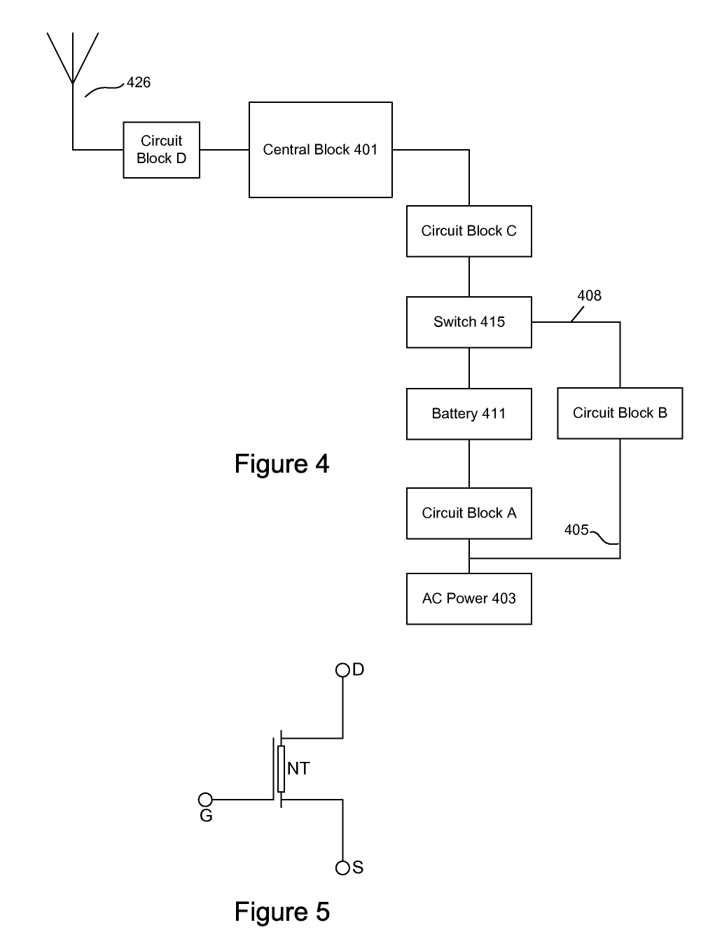

FIG. 4 shows a more detailed block diagram of a representative system incorporating the invention. This is an exemplary system representative of an electronic device, notebook computer, vehicle, telecommunications network, or other system incorporating the invention as discussed above. The system has a central block 401, a component of the system receiving power. The central block may be a central processing unit, microprocessor, memory, amplifier, electric motor, display, or other.

DC power is supplied to the central block from a rechargeable battery 411. This battery is charged from an AC power source 403 using a circuit block A including carbon nanotube transistors or devices of the invention. Circuit block A may include circuitry to convert AC power to DC power, and this circuitry may also include carbon nanotube transistors or rectifying devices. Although a single circuit block A is shown to simplify the diagram, the circuitry may be divided into two circuit blocks, one block for AC-to-DC conversion and another block for the recharging circuitry.

Central block may be a device that can be powered either by the AC line or from the battery. In such an embodiment, there would be a path from AC power, connection 405, circuit block B, and connection 408 to a switch 415. The battery is also connected to switch 415. The switch selects whether power is supplied to the central block from the battery or from the AC power line (via circuit block B). Circuit block B may include AC-to-DC conversion circuitry implemented using carbon nanotube transistors or devices of the invention. Furthermore, in an implementation of the invention, switch 415 includes carbon nanotube transistors or devices of the invention.

Circuit block B may be incorporated into a power supply for central block. This power supply may be switching or linear power supply. With carbon nanotube transistors of the invention, the power supply will be able to provide more power in a more compact form factor than using typical transistors. The power supply of the invention would also generate less heat, so there is less likelihood of overheating or fire. Also, a fan for the power supply may not be necessary, so a system incorporating a power supply having nanotube transistors of the invention will be quieter.

The path from AC power through circuit block B is optional. This path is not needed in the case there is not an option to supply power from an AC line to the central block. In such a case, switch 415 would also not be used, and battery 411 would directly connect to circuit block C. As can be appreciated, there are many variations to how the circuitry of the system in the figure may be interconnected, and these variations would not depart from the scope of the invention.

Circuit block C is circuitry such as a DC-to-DC power converter or voltage regulator including carbon nanotube transistors or devices of the invention. This circuitry takes DC power of a certain voltage and converts it to DC voltage at a different voltage level. For example, the battery or output of circuit block B may have an output voltage of about 7.2 volts, but the central block uses 3 volts. Circuit block C converts the 7.2 volts to 3 volts. This would be a step-down converter since voltage of a higher level is being converted to a lower level.

In the case central block 401 has a wireless component, a path including circuit block D and antenna 426 will be used to transmit and receive wireless signals. Circuit block includes carbon nanotube transistors of the invention to perform the signal transmission or reception. For example, the carbon nanotube transistors may be used as output devices in an amplifier generating the wireless signal. In an implementation of the invention without a wireless component, then circuit block D and the antenna would not be present.

FIG. 5 shows a symbol of a carbon nanotube transistor of the invention. According to the invention, transistors are manufactured using carbon nanotubes (CNTs). And more specifically, field-effect transistors (FETs) are manufactured using single-walled carbon nanotubes. The transistor has a gate node G, drain node D, and source node S. This carbon nanotube transistor of the invention does not have a bulk, substrate, or well node as would a typical MOS transistor of an integrated circuit. In other embodiments of the invention, the carbon nanotube transistor may have a bulk node.

When an appropriate voltage is applied to the gate node, a channel can form in a carbon nanotube, denoted by NT. Current can flow from drain to source. Operation of the single-walled carbon nanotube transistor of the invention is analogous to a metal oxide semiconductor (MOS) transistor.

The single-walled carbon nanotube is a relatively recently discovered material. A single-walled carbon nanotube can be conceptually described as a single sheet of graphite (also called graphene) that is configured into a seamless cylindrical roll with diameters typically about 1 nanometer, but can range from about 0.4 to about 5 nanometers. The cylinder may be a one-layer thick layer. For example, a nanotube may be 0.5, 0.7, 0.8, 0.9, 1.0, 1.1, 1.2, 1.3, 1.6, 2, 2.5, 2.7, 3, 3.2, 3.6, 3.8, 4.0, 4.2, 4.3, 4.5, 4.6, 4.7, or 4.9 nanometers. Depending on the process technology, single-walled carbon nanotubes may have diameters less than 0.7 nanometers or greater than 5 nanometers.

In addition to single-walled carbon nanotubes, another type of carbon nanotube is a multiwalled carbon nanotube (MWNT). A multiwalled carbon nanotube is different from single-walled carbon nanotube. Instead of a single carbon nanotube cylinder, multiwalled carbon nanotubes have concentric cylinders of carbon nanotubes. Consequently, multiwalled carbon nanotubes are thicker, typically having diameters of about 5 nanometers and greater. For example, multiwalled carbon nanotubes may have diameters of 6, 7, 8, 10, 11, 15, 20, 30, 32, 36, 50, 56, 62, 74, 78, 86, 90, 96, or 100 nanometers, or even larger diameters.

Single-walled carbon nanotubes have unique electrical, thermal, and mechanical properties. Electronically they can be metallic or semiconducting based on their chirality or helicity, which is determined by their (n, m) designation, which can be thought of as how the graphite sheet is rolled into a cylinder. Typically, individual single-walled carbon nanotubes can handle currents of 20 microamps and greater without damage. Compared to multiwalled carbon nanotubes, single-walled carbon nanotubes generally do not have structural defects, which is significant for electronics applications.

Single-walled carbon nanotube material has proven to have incredible materials properties. It is the strongest known material—about 150 times stronger than steel. It has the highest known thermal conductivity (about 6000 W/m·K). Semiconducting single-walled carbon nanotubes have excellent properties. These nanotubes may be used in field-effect transistors (FETs), nonvolatile memory, logic circuits, and other applications.

With regard to transistor applications, single-walled nanotube devices have “on” resistances and switching resistances that are significantly lower than those of silicon. Transistors based on single-walled carbon nanotube technology can handle considerably higher current loads without getting as hot as conventional silicon devices. This key advantage is based on two factors. First, the lower “on” resistance and more efficient switching results in much lower heat generation. Second, single-walled carbon nanotubes have high thermal conductivity ensures that the heat does not build up.

Important considerations in carbon nanotube field effect transistor (CNTFET) design and fabrication are threefold. A first consideration is the controlled and reproducible growth of high quality single-walled carbon nanotubes with the desirable diameter, length, and chirality. A second consideration is the efficient integration of nanotubes into electronic structures. And a third consideration is current nanotube growth and device fabrication processes need to be improved significantly so that they are amenable to scalable and economical manufacturing.

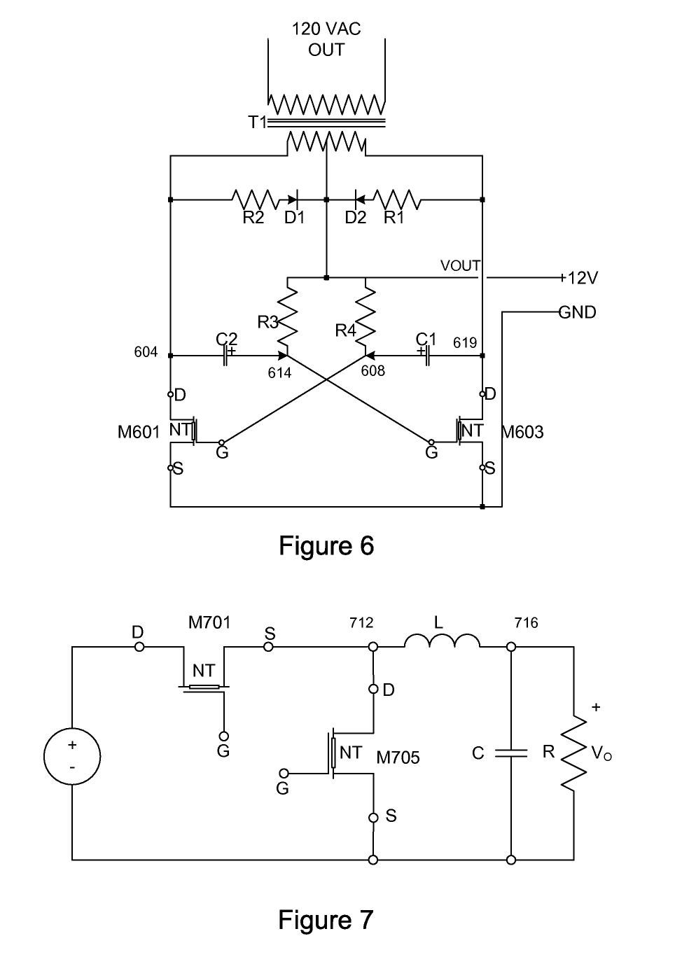

FIG. 6 shows an AC-to-DC converter circuit using two carbon nanotube transistors, M601 and M603, of the invention. The circuitry takes an AC voltage input, such as 120 volts provided at transformer T1 and provides a DC voltage output, such as the 12 volts indicated in the figure. The converter may be designed to take as input any AC voltage, but 120 volts was selected since this is the standard AC line voltage in the U.S. The circuitry may be designed to output any desired DC voltage, less than or more than 12 volts, such as 2 volts, 3, volts, 5 volts, 6 volts, 16 volts, 18 volts, or 20 volts, by varying the circuit components. For example, the resistances R1, R2, R3, and R4 may be varied.

Single-walled carbon nanotube transistor M601 is connected between a node 604 and ground. A gate node of M601 is connected to node 608. A capacitor C2 is connected between 604 and 614, which is connected to a gate of single-walled carbon nanotube transistor M603. M603 is connected between node 619 and ground. A capacitor C1 is connected between 608 and 619. Resistor R3 is connected between DC output, VOUT, and 614. Resistor R4 is connected between VOUT and 608. Between VOUT and 604 are a diode D1 and resistor R2. Between VOUT and 619 are a diode D2 and resistor R1. Nodes 604 and 619 are connected to windings of transformer T1.

The AC-to-DC converter may output significant currents because the converter provides power for circuits having relatively large power needs. Therefore, in such cases, carbon nanotube transistors M601 and M603 will pass relatively large currents. In addition, in a battery recharging battery application, by increasing the current M601 and M603 can pass without overheating or damaging the devices, this will speed-up the rate at which batteries may be recharged.

FIG. 7 shows a DC-to-DC converter circuit using two carbon nanotube transistors, M701 and M705, of the invention. The circuit takes a DC input voltage, VIN, and outputs a different DC voltage, VO. For example, VIN may be 7.2 volts or 12 volts, and VO may be 5 volts or 3 volts. Voltage conversion is used in many applications such as portable electronics because batteries may not provide output at a desired voltage level or at a voltage compatible with electronics.

This circuit may also be part of a DC inverter circuit, in which case a voltage output of opposite polarity to the input voltage is provided. For example, if the input voltage is positive, the output voltage of the inverter would be negative. Or if the input voltage is negative, the output voltage of the inverter would be positive.

Single-walled carbon nanotube transistor M701 is connected between VIN+ and node 712. Single-walled carbon nanotube transistor M705 is connected between node 712 and VIN− (or ground). An inductor L is connected between 712 and 716. A capacitor and resistor are connected between 716 and VIN−. An output VO is taken between node 716 and ground.

In a further embodiment of the invention, there may be a first diode connected between a drain and source of transistor M701, and a second diode connected between a drain and source of transistor M705. The first diode may be connected so that current will be allowed to flow in a direction from node 712 to VIN+. The second diode may be connected so that current will be allowed to flow in a direction from ground to node 712.

These diodes may be designed or fabricated using any technique used to obtain devices with diode characteristics including using a diode-connected transistor, where a gate and drain of the transistor are connected together, or other transistor techniques. In another embodiment, a diode may be integrated with a nanotube transistor using a single-walled carbon nanotube and nanowire junction (e.g., a nanotube-nanowire device, where the device is a nanotube joined to a a nanowire) or other junction as will be discussed in more below.

In operation, the converter circuit converts the VIN voltage to a VO or VOUT voltage. A first signal is connected to a gate of transistor M701, and a second signal is connected to a gate of transistor M705. The first and second signals may clock signals or oscillator signals including square waves, pulse trains, sawtooth signals, and the like. The first and second signals and may be generated by a controller for the converter circuit.

Power transistors are high power output stages in electronics that typically carry high currents and power. They are elements in power amplifiers and are used to deliver required amounts of current and power efficiently to a load. Applications include power delivery to devices within integrated circuits, personal computers, cellular phones, wireless base stations, and a variety of electrical devices. Power transistors are also used for high current switches and supplying power to motors.

At the present time, power transistors are bipolar junction transistors (BJT) or metal oxide semiconductor field-effect transistors (MOSFET) based on silicon technology. In addition to these silicon-based devices, other materials are used such as gallium arsenide and gallium nitride. However, silicon bipolar junction transistors and silicon metal oxide semiconductor field-effect transistors, specifically laterally diffused metal oxide semiconductor, dominate the field. The entire power transistor device contains a multitude of linked individual transistors in order to distribute the total current and power. Relevant parameters in power transistors include current carrying and power capability, current gain, efficiency, and thermal resistance.

Nanotube- and nanowire-based devices such as sensors, transistors, diodes, and other electronic devices are manufacturable in a single level in a horizontal structure. Carbon nanotubes transistors having a single nanotube or a few nanotubes have characteristics comparable to or better than current silicon or semiconductor technology. Nanowires and nanowire networks are useful for applications such as sensors, transistors, and diodes and also for single nanowire devices or structures or for a device or structure having many nanowires between electrodes.

Single nanotube or nanowire devices and multiple nanotube or nanowire devices (e.g., thousands and more) can be fabricated. However, there is a limitation on the density and total number of nanotubes or nanowires when using a horizontal architecture. For example, each carbon nanotube has a resistance and current capability. Each nanotube generally has a relatively small current carrying capability. Therefore, in order to handle the currents used in devices in typical commercial applications, large number of these nanoscale materials will generally be needed. It will take numerous nanotube devices connected in parallel to handle electrical current from several hundred milliamps up to tens of amps or even greater. The current density of devices using a single horizontal layer may not be sufficient to achieve the required current for applications and required resistances and electronic properties, especially since it is desirable to fabricate circuits providing greater current density or current carrying capability in a relatively small area.

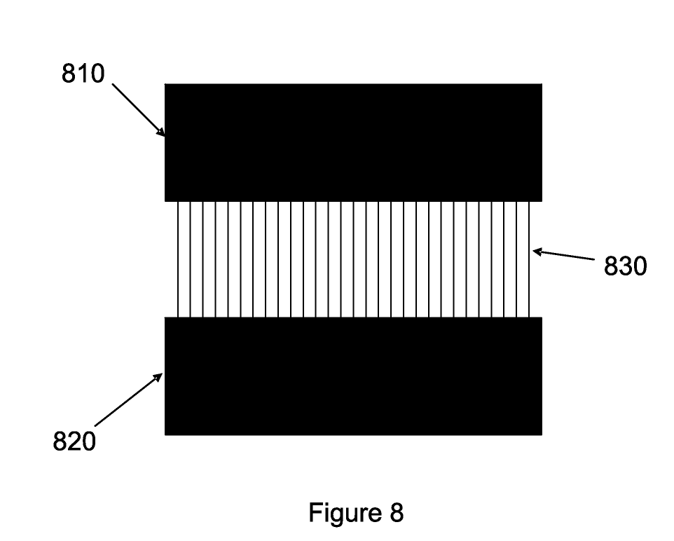

FIG. 8 shows a top view of an example of a horizontal structure with nanotubes or nanowires between two electrodes. There are two electrodes 810 and 820 with many nanotubes or nanowires 830, or a combination of nanotubes and nanowires, connected to the electrodes. The figure shows an example of how the nanotubes or nanowires can be organized. In other implementations, the arrangement may be electrically similar to or electrically the same as what is shown, but the layout may be different. For example, nanotubes, nanowires, electrodes, or other features of the layout may be placed in a serpentine, circular, T-shaped, Y-shaped, or any other shape may be used.

The electrodes are typically made of a metal (such as aluminum or copper) or other conductor or conductive material (e.g., polysilicide or polysilicon). An electrode may be formed by using different conductors connected together. For example, the electrode may be segments of metal strapped together using polysilicon jumpers. Further, the parts of an electrode may be on different process layers such as having portions on metal-1 and other portions on metal-2.

In a basic configuration, one end of each nanotube or nanowire contacts the one electrode (e.g., electrode 810) and the other end of each nanotube or nanowire contacts the other electrode (e.g., electrode 820). Using a structure such as in this figure, electronic devices (including transistors, sensors, diodes, and so forth) having one or many nanotubes or nanowires are manufacturable having the desired characteristics and properties.

In a specific embodiment, each nanotube is a single-walled carbon nanotube. In a specific embodiment, each nanotube is a multiwalled carbon nanotube. In further embodiments, the nanotubes include a combination of single-walled carbon nanotubes and multiwalled carbon nanotubes. In a specific embodiment, a structure may include any combination of nanotubes and nanowires. For example, nanotube may be connected or joined to nanowires to form a combined nanotube-nanowire structure.

The single-walled carbon nanotube is a relatively recently discovered material. A single-walled carbon nanotube can be conceptually described as a single sheet of graphite (also called graphene) that is configured into a seamless cylindrical roll with diameters typically about 1 nanometer, but can range from about 0.4 to about 5 nanometers. The cylinder may be a single-layer thick layer. For example, a nanotube may be 0.5, 0.7, 0.8, 0.9, 1.0, 1.1, 1.2, 1.3, 1.6, 2, 2.5, 2.7, 3, 3.2, 3.6, 3.8, 4.0, 4.2, 4.3, 4.5, 4.6, 4.7, or 4.9 nanometers. Depending on the process technology used, single-walled carbon nanotubes may have diameters less than 0.7 nanometers or greater than 5 nanometers.

In addition to single-walled carbon nanotubes, another type of carbon nanotube is a multiwalled carbon nanotube (MWNT). A multiwalled carbon nanotube is different from single-walled carbon nanotube. Instead of a single carbon nanotube cylinder, multiwalled carbon nanotubes have concentric cylinders of carbon nanotubes. Consequently, multiwalled carbon nanotubes are thicker, typically having diameters of about 5 nanometers and greater. For example, multiwalled carbon nanotubes may have diameters of 6, 7, 8, 10, 11, 15, 20, 30, 32, 36, 50, 56, 62, 74, 78, 86, 90, 96, or 100 nanometers, or even larger diameters.

Depending on the fabrication process used, the nanotubes may be formed before or after the electrodes are formed. For example, in one process, the electrodes are patterned and formed (e.g., using a photolithography process) and then the nanotubes are formed above or on top of the electrodes.

During the fabrication of nanotubes, desirable and undesirable nanotubes may be formed. Some nanotubes may have undesirable characteristics. For example, some nanotubes may be metallic single-walled carbon nanotubes or semiconducting single-walled carbon nanotubes that do not deplete effectively with the electric gating. These undesirable carbon nanotube devices can be removed by any competent technique such as chemical, mechanical, or electrical techniques, and the like, or combinations of these techniques. One specific technique is to use acids such as nitric acid to etch metallic tubes at a faster rate than semiconductors.

Another technique to remove undesirable nanotubes is electrical burn-off. For example, in an implementation, current above a certain amount will cause the undesirable nanotubes to burn-off (e.g., vaporize or become open) while the desirable nanotubes remain.

The structure in FIG. 8 may be used to form a transistor. In one implementation, a gate electrode can be run over (or below) the nanotubes, separated by a gate dielectric. In another implementation, the nanotubes each include a gate electrode that surrounds the nanotube. This is a concentric gate electrode. See U.S. patent application Ser. No. 11/465,912, which is incorporated by reference, for more discussion. A concentric gate surrounds at least a portion of each nanotube. In another implementation, between each of the nanotubes or between groups of nanotubes (e.g., between every two, three, four, or n nanotubes, when n is an integer), a gate electrode is placed. The gate electrode may be formed from any material such as metal, polysilicon, or other suitable material.

If the device is a transistor, a technique is electrical burn-off with protection where the gate is used to turn off the “wanted” semiconducting tubes (e.g., a negative voltage or sufficiently low voltage can be used) and then flow a sufficient current through the metallic tubes until they fail. The current to cause failure or electrical breakdown of the undesirable carbon nanotubes may be over above about 15 microamps to about 25 microamps per tube, or even higher currents may be used. Due to the redundancy and device density, even in the case when nanotubes yield as an effective single-walled carbon nanotube device, this will not render the transistor device defective or inoperative.

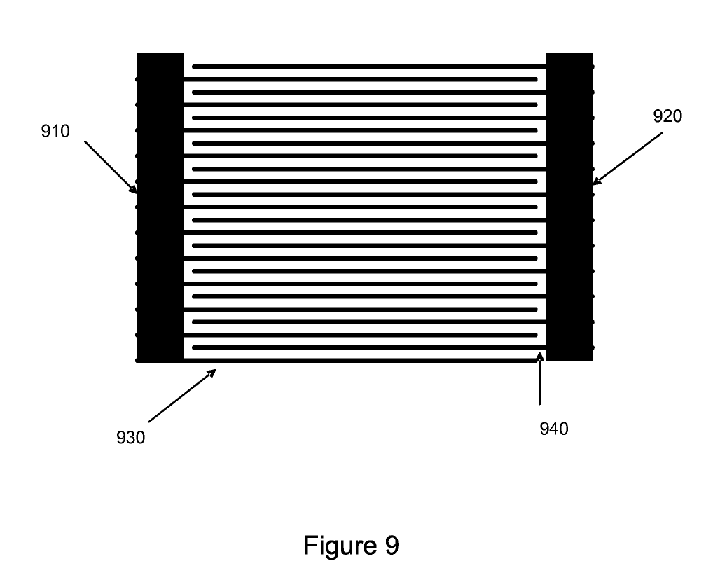

FIG. 9 shows a top view of a structure with interdigitated electrodes. This structure can be used to increase the total number of nanotube or nanowire devices in a given area. In order to simplify the diagrams, for FIGS. 9-11, only the electrodes are shown, and not the nanotubes or nanowires connected to the electrodes. It should be understood that the nanotubes or nanowires will be formed and connect to the electrodes in a similar fashion as was shown for FIG. 8; the nanotubes or nanowires are run perpendicular to the interdigitated electrode fingers.

Electrode 910 has a number of fingers 930 that extend to the right (in this figure) and are interdigitated with fingers 940 (extending from the left) from an opposite electrode 920. This provides the possibility for many connections and increased density over other structures such as FIG. 8.

In an implementation, nanotubes or nanowires may be connected similarly as shown in FIG. 8. A nanotube or nanowire is placed across a two adjacent electrodes. In another implementation, a nanotube or nanowire is placed across a three electrodes. The middle electrode, between two outer electrodes, is a first electrode of a device. The two outer electrodes are connected together to form a second electrode of the device.

In another implementation, single long nanotubes or nanowires may be divided into many segments by the interdigitated electrode fingers, where each segment may be a device that contributes to the total current. For example, one long electrode is run across a number of the fingers. Appropriate members of the fingers are connected together so a working device if formed.

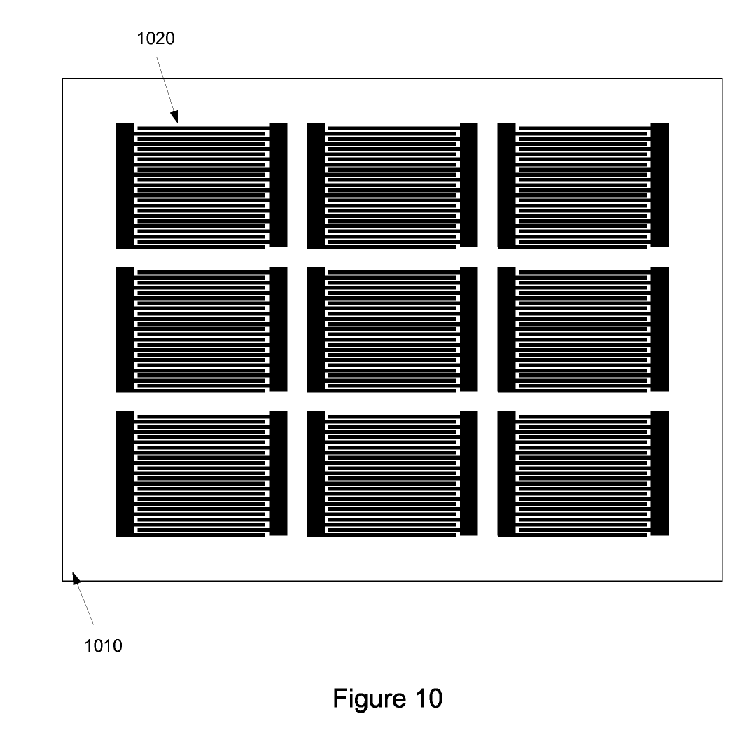

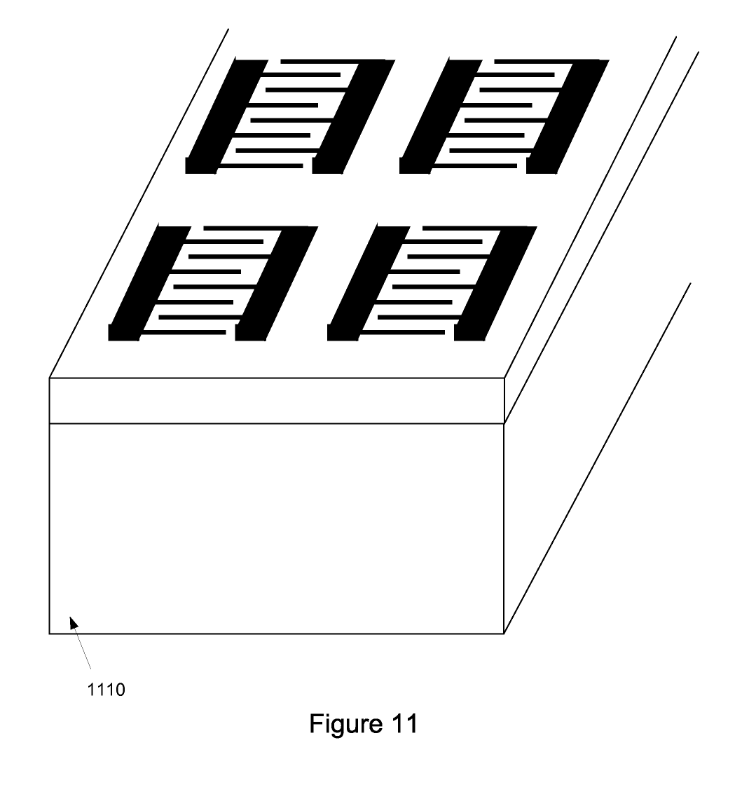

FIG. 10 shows a top view of a substrate or integrated circuit die (or portion of an integrated die) with a number of interdigitated structures of FIG. 9. In this figure, the die has nine interdigitated structures, but in other implementations, there may be any number of such structures, one, two, three, four, five, six, seven, eight, nine, or more than nine. Further, in some embodiments, any number of the individual interdigitated structures maybe interconnected with each other to form a network of interdigitated structures, which will have, for example, greater current handling capability than individual structures. The structures may be connected in parallel or in series as desired.

For example, a first electrode of a first interdigitated structure is connected to a first electrode on a second interdigitated structure. A second electrode of the first interdigitated structure is connected to a second electrode on the second interdigitated structure. Any number of interdigitated structures can be connected in such a fashion.

Even when using an interdigitated structure approach and forming a number of such structures on a horizontal layer, there is a limit to the number of nanotubes or nanowires that can be synthesized or deposited and connect to the electrodes. It is difficult to closely pack the nanotubes or nanowires to obtain an appreciable density without negatively affecting the performance of the device or materials.

A technique of increasing the density of nanotubes or nanowires is by stacking layers or forming multiple layers of interdigitated structures. As FIG. 11 shows, a single layer or level of devices is fabricated on a substrate 1110. After fabrication, this substrate may be removed or lapped as desired. Nanotubes or nanowires may be synthesized directly on the level or deposited on by conventional techniques such as spin coating, dropwise, microfluidics, and other techniques. Additional layers are fabricated directly on top of this first level. As many layers as desired may be added. The stacking allows for many more devices per unit area without adding to the size of the packages, since each layer is relatively thin.

FIG. 11 shows the use of interdigitated electrode structures for nanotubes or nanowires on the first layer. However, as one of skill in the art will recognize, the invention is applicable to other electrode structures for nanotubes or nanowires. In other embodiments of the invention, an electrode structure similar to that shown in FIG. 8 may be used instead of an interdigitated structure. The stacking feature of the invention is applicable any electrode structure for nanotubes or nanowires.

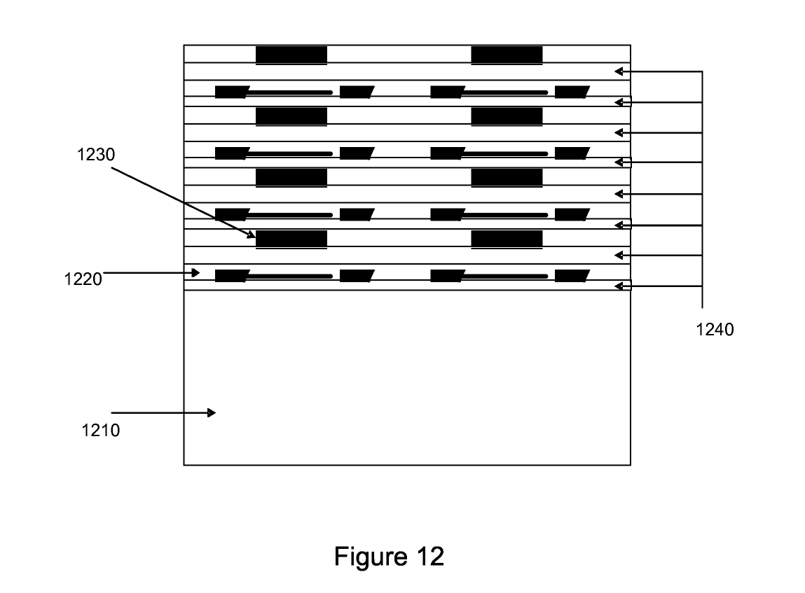

FIG. 12 shows a cross-sectional view of a substrate with multiple layers of structures with nanotubes or nanowires. A first level of devices 1220 is formed on a substrate 1210. There is a patterned gate layer 1230, such as a metal or polysilicon or similar gate material that is used to modulate the properties of the nanotubes or nanowires, or both, such as in transistor applications. There are multiple insulator layers 1240 used to separate device layers and conductive gate layers. There may be any number of layers of devices, gates, and insulators as desired.

Further, optional heat sink or electrical screening layers, or a combination of these, may be deposited in between the layers. These layers may be used to remove heat from a particular device level more efficiently.

Thicknesses of the insulating layers 1240 may vary, especially since this insulating layer may be the gate oxide layer (i.e., oxide between the gate region and nanotubes which form the channel regions). The quality and thickness of the gate oxide will influence the transistor characteristics. The gate oxide may be silicon oxide.

In an implementation, an insulating or insulator layer below the gate is thinner than the insulating layer above the gate. This may be because the gate forms a transistor with the structures below the gate, but not above the gate. In an implementation, an insulating layer above the gate is thinner than the insulating layer below the gate. This may be because the gate forms a transistor with the structures above the gate, but not below the gate. Further, insulating layers above and below a gate region may both be used as gate oxides. This may be a situation whether the devices above and below the gate are connected in parallel, and will operate a single larger sized transistor. The gate will be a gate with nanotube transistor elements (channels) above and below the gate.

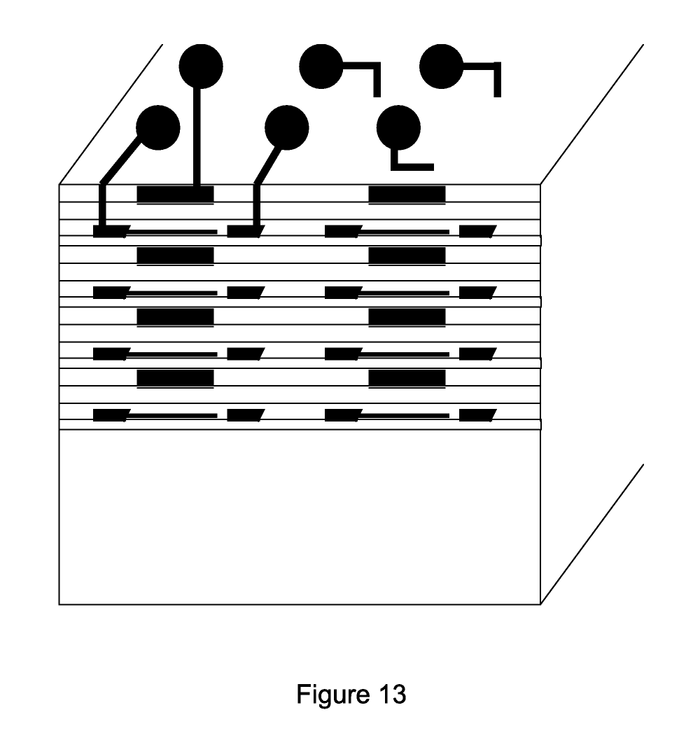

FIG. 13 shows a perspective view of a multilayer structure with interconnects and vias for electrical connection to the various device levels. This allows for wire bond, bump, or other connection and packaging. The interconnects or vias, or both, may be formed using conventional techniques or use nanotubes or nanowires.

This description of the invention has been presented for the purposes of illustration and description. It is not intended to be exhaustive or to limit the invention to the precise form described, and many modifications and variations are possible in light of the teaching above. The embodiments were chosen and described in order to best explain the principles of the invention and its practical applications. This description will enable others skilled in the art to best utilize and practice the invention in various embodiments and with various modifications as are suited to a particular use. The scope of the invention is defined by the following claims.

The invention claimed is:

1. A structure comprising:
a substrate;
a first layer formed on the substrate, the first layer comprising a first electrode interdigitated with a second electrode;
a first plurality of nanotubes coupled to the first and second electrodes;
a second layer comprising an insulating material formed on the first layer;
a third layer comprising a first gate material formed on the second layer, wherein the first gate material is positioned above the first plurality of nanotubes; and
a fourth layer comprising an insulating material formed on the third layer.

2. The structure of claim 1 comprising:
a fifth layer formed on the fourth, the fifth layer comprising a third electrode interdigitated with a fourth electrode;
a second plurality of nanotubes coupled to the third and fourth electrodes; and
a sixth layer comprising an insulating material formed on the fifth layer.

3. The structure of claim 1 wherein the gate material is polysilicon.

4. The structure of claim 2 wherein the second plurality of nanotubes are formed above the gate material.

5. A structure comprising:
a substrate;
a first layer formed on the substrate, the first layer comprising a first electrode interdigitated with a second electrode;
a first plurality of nanowires coupled to the first and second electrodes;
a second layer comprising an insulating material formed on the first layer;
a third layer formed above the second layer, the second layer comprising a third electrode interdigitated with a fourth electrode; and
a second plurality of nanowires coupled to the third and fourth electrodes.

6. A structure comprising:
a substrate;
a first layer formed on the substrate, the first layer comprising a first electrode interdigitated with a second electrode;
a first plurality of nanotubes coupled to the first and second electrodes;
a second layer comprising an insulating material formed on the first layer;
a third layer formed above the second layer, the second layer comprising a third electrode interdigitated with a fourth electrode; and
a second plurality of nanotubes coupled to the third and fourth electrodes.

7. The structure of claim 6 wherein the nanotubes are single-walled carbon nanotubes.

8. The structure of claim 6 wherein the nanotubes are multiwalled carbon nanotubes.

9. An electronic system comprising a structure as recited in claim 1.

10. An electronic system comprising a structure as recited in claim 5.

11. An electronic system comprising a structure as recited in claim 6.

12. A method comprising:
forming on a first layer, a first electrode comprising first fingers;
forming on the first layer a second electrode comprising second fingers, wherein the second fingers are interdigitated with the first fingers;
forming a second layer above the first layer;
forming a gate electrode in a third layer above the second layer, wherein the gate electrode is above at least a portion of the first and second fingers;
forming a fourth layer above the third layer;
forming on a fifth layer, above the fourth layer, a third electrode comprising third fingers; and
forming on the fifth layer a fourth electrode comprising fourth fingers, wherein the fourth fingers are interdigitated with the third fingers, and the gate electrode is below at least a portion of the fourth and fifth fingers.

13. The method of claim 12 comprising:
forming nanotubes on the first layer, each nanotube coupled to the first and second electrodes; and
forming nanotubes on the fifth layer, each nanotube coupled to the third and fourth electrodes.

14. The method of claim 12 comprising:
forming nanowires on the first layer, each nanowire coupled to the first and second electrodes; and
forming nanowires on the fifth layer, each nanowire coupled to the third and fourth electrodes.

15. The method of claim 12 comprising:
forming nanotubes on the first layer, each nanotube coupled to the first and second electrodes; and
forming nanowires on the fifth layer, each nanowire coupled to the third and fourth electrodes.

16. The method of claim 13 comprising:
applying a first voltage on the gate electrode; and
applying a voltage potential across the first and second electrodes sufficient to cause current to flow through undesirable nanotubes of the nanotubes on the first layer, but current does not flow through desirable nanotubes.

17. The method of claim 16 wherein the first voltage is a negative voltage.

18. A method comprising:
forming on a first layer, a first electrode comprising first fingers;
forming on the first layer a second electrode comprising second fingers, wherein the second fingers are interdigitated with the first fingers;
forming a first plurality of nanotubes coupled to the first and second electrodes, wherein each nanotube comprises a concentric gate surrounding the nanotube;
forming a second layer above the first layer;
forming on a third layer, above the second layer, a third electrode comprising third fingers;
forming on the third layer a fourth electrode comprising fourth fingers, wherein the fourth fingers are interdigitated with the third fingers; and
forming a second plurality of nanotubes coupled to the third and fourth electrodes, wherein each nanotube comprises a concentric gate surrounding the nanotube.

19. The method of claim 18 wherein each nanotube is a single-walled carbon nanotube.

20. A method comprising:
forming on a first layer, a first electrode comprising first fingers;
forming on the first layer a second electrode comprising second fingers, wherein the second fingers are interdigitated with the first fingers;
forming a first plurality of nanotube-nanowire devices coupled to the first and second electrodes, wherein each nanotube comprises a concentric gate surrounding the nanotube;
forming a second layer above the first layer;
forming on a third layer, above the second layer, a third electrode comprising third fingers;
forming on the third layer a fourth electrode comprising fourth fingers, wherein the fourth fingers are interdigitated with the third fingers; and
forming a second plurality of nanotube-nanowire devices coupled to the third and fourth electrodes, wherein each nanotube comprises a concentric gate surrounding the nanotube.
